(19) United States
(12) Patent Application Publication
(10) Pub. No.: US 2024/0311542 A1
(43) Pub. Date: Sep. 19, 2024

(54) RECTILINEAR-BLOCK PLACEMENT METHOD FOR EARLY FLOORPLAN USING REINFORCEMENT LEARNING

(71) Applicant: MEDIATEK INC., Hsin-Chu (TW)

(72) Inventors: Jen-Wei Lee, Hsinchu City (TW); Yi-Ying Liao, Hsinchu City (TW); Te-Wei Chen, Hsinchu City (TW); Kun-Yu Wang, Hsinchu City (TW); Sheng-Tai Tseng, Hsinchu City (TW); Ronald Kuo-Hua Ho, Hsinchu City (TW); Bo-Jiun Hsu, Hsinchu City (TW); Wei-Hsien Lin, Hsinchu City (TW); Chun-Chih Yang, Hsinchu City (TW); Chih-Wei Ko, Hsinchu City (TW); Tai-Lai Tung, Hsinchu City (TW)

(73) Assignee: MEDIATEK INC., Hsin-Chu (TW)

(21) Appl. No.: 18/396,711

(22) Filed: Dec. 27, 2023

Related U.S. Application Data
(60) Provisional application No. 63/489,788, filed on Mar. 13, 2023.

(51) Int. Cl. G06F 30/392

(52) U.S. Cl. CPC G06F 30/392

(57) ABSTRACT

A rectilinear-block placement method includes disposing a first sub-block of each flexible block on a layout area of a chip canvas according to a reference position, generating an edge-depth map relative to first sub-blocks of flexible blocks on the layout area, predicting positions of second sub-blocks of the flexible blocks with depth values on the edge-depth map by a machine learning model, and positioning the second sub-blocks on the layout area according to the predicted positions of the second sub-blocks of the flexible blocks.

### CROSS REFERENCE TO RELATED APPLICATIONS

This application claims the benefit of U.S. Provisional Application No. 63/489,788, filed on Mar. 13, 2023. The content of the application is incorporated herein by reference.

### BACKGROUND

Floorplanning is an early stage in integrated circuit (IC) design. During the floorplanning stage, circuit designers explore options for placing circuit blocks on a chip canvas, and the register-transfer level (RTL) code and netlist of the circuit blocks have not been generated yet.

Macro placement following the floorplanning stage is performed after one or more placement options are selected. A macro contains post-synthesized descriptions of a circuit block. The logic and electronic behavior of the macro are given but the internal structural description of the macro may still be unknown. Placing macros of various sizes on a chip canvas is a challenging task when an objective such as the wirelength, congestion, etc is to be optimized.

In various stages of the IC design flow, the number of circuit blocks involved in the placement can be in the order of hundreds or thousands. The placement of circuit blocks is a complicated and time-consuming process and typically relies on the expertise of chip designers. The reliance on manual efforts severely limits the number of placement options that can be explored within a reasonable time. As a result, the manual placement may be suboptimal. If the chip design later calls for a different placement, the high iteration cost and impact on the schedule and resources would be prohibitive. Thus, there is a need to improve the quality and efficiency of circuit block placement.

### SUMMARY

In an embodiment, a rectilinear-block placement method includes disposing a first sub-block of each flexible block on a layout area of a chip canvas according to a reference position, generating an edge-depth map relative to first sub-blocks of flexible blocks on the layout area, predicting positions of second sub-blocks of the flexible blocks with depth values on the edge-depth map by a machine learning model, and positioning the second sub-blocks on the layout area according to the predicted positions of the second sub-blocks of the flexible blocks.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a rectilinear-block placement method for circuit block placement according to an embodiment of the present invention.

FIG. 2 is the block diagram of an architecture of the machine learning model used in the rectilinear-block placement method in FIG. 1.

FIG. 3 shows a placement state in M×N grids according to an embodiment of the present invention.

FIG. 4 shows sequentially disposed sub-blocks of a flexible block according to an embodiment of the present invention.

FIG. 5A shows an edge-depth map according to an embodiment of the present invention.

FIG. 5B shows a placement decision according to the edge-depth map in FIG. 5A.

FIG. 6 shows the definitions of various areas that are utilized to calculate the rewards of the reinforcement learning according to an embodiment of the present invention.

### DETAILED DESCRIPTION

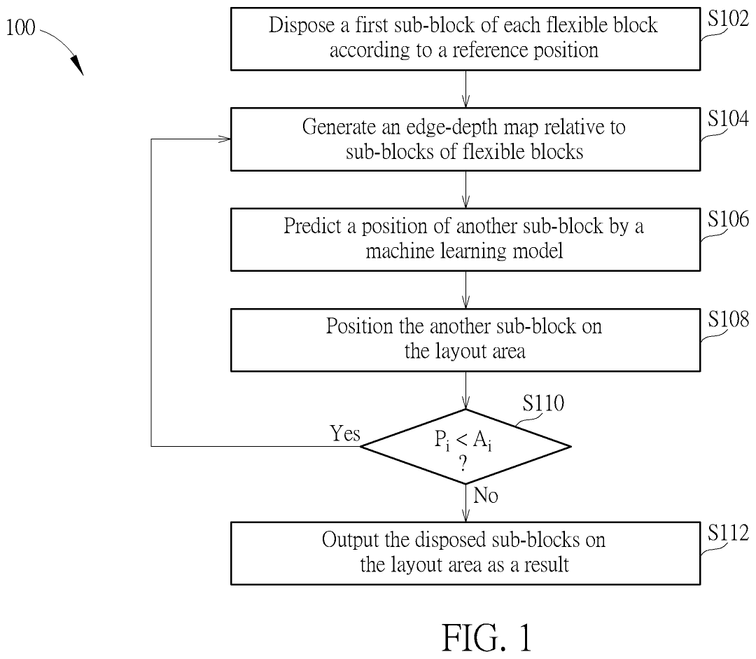

FIG. 1 is a flow chart of a rectilinear-block placement method 100 for circuit block placement according to an embodiment of the present invention. The rectilinear-block placement method (EdgeShaper) 100 includes the following steps:

Step S102: dispose a first sub-block of each flexible block on a layout area of a chip canvas according to a reference position;

Step S104: generate an edge-depth map relative to disposed sub-blocks of flexible blocks on the layout area;

Step S106: predict a position of another sub-block of the flexible block with depth values on the edge-depth map by the machine learning model;

Step S108: position the another sub-block on the layout area according to the predicted position of the another sub-block of the flexible block;

Step S110: check if the placed area Pᵢ is smaller than the area Aᵢ of the flexible block; if so, go to step S104; else go to step S112; and

Step S112: output the disposed sub-blocks on the layout area as a result.

In step S102, the first sub-block of each flexible block is disposed on a layout area of a chip canvas according to a reference position. The reference position of flexible blocks may be obtained from the placement phase of a commercial tool, where the reference position may be the center point of initial blocks. In step S104, the edge-depth map is generated relative to the disposed sub-blocks of flexible blocks on the layout area. The edge-depth map is composed of distances from grids to the sub-blocks. In step S106, a position of another sub-block of the flexible block with depth values on the edge-depth map is predicted by a machine learning model. The machine learning model is trained by reinforcement learning and composed of convolutional neural network (CNN), deep neural network (DNN) or other deep learning models.

In step S108, the another sub-block is positioned on the layout area according to the predicted position of the another sub-block of the flexible block. In step S110, the placed area Pᵢ of the ith flexible block is calculated to compute the area of disposed sub-blocks. If Pᵢ is smaller than the total area Aᵢ of the flexible block, go to step S104 to perform a recursive process, else go to step S112. In step S112, the disposed sub-blocks on the layout area are outputted as a result.

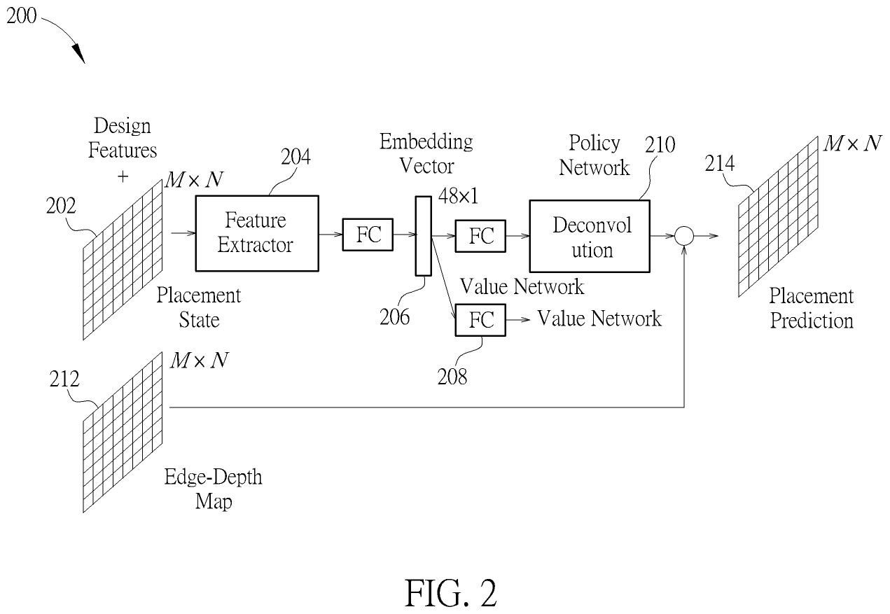

FIG. 2 is the block diagram of an architecture 200 of the machine learning model used in the rectilinear-block placement method 100. At first, design features and a placement state 202 are inputted to a feature extractor 204 to generate an embedding vector 206 with n dimensions. In an embodiment, n is 48. Secondly, the embedding vector 206 is inputted to a policy network 210 to generate a two-dimensional tensor 214 representing an action probability of position on M×N grids. Third, the two-dimensional tensor 214 on the edge-depth map 212 is applied to explore a potential placement of the another sub-block at an edge of disposed sub-blocks of the flexible block.

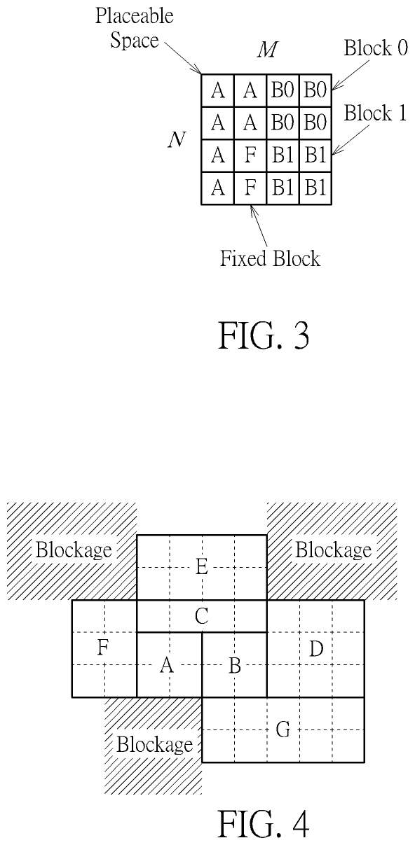

In an embodiment, the feature extractor 204 comprises a three layer convolution and a fully connected network. The policy network 210 comprises a fully connected network and a deconvolutional network. The design features comprise areas, reference positions, connection maps, and physical constraints of the flexible blocks, and areas of the disposed sub-blocks of the flexible blocks. The placement state 202 comprises the positions of disposed sub-blocks, which is depicted in FIG. 3.

FIG. 3 shows the placement state 202 in M×N grids according to an embodiment of the present invention. The numbers in M×N grids represent different states. A means the grid is placeable or available for placing, F means the grid is placed by a fixed block, B0 means the grid is placed by a flexible block 0, and B1 means the grid is placed by a flexible block 1. By feeding this placement state 202 into the machine learning model, the features of the placement state 202 in M×N grids can be extracted to a 48×1 embedding vector 206 by the feature extractor 204. Then, a placement action can be generated by the policy network 210 to optimize the circuit block placement.

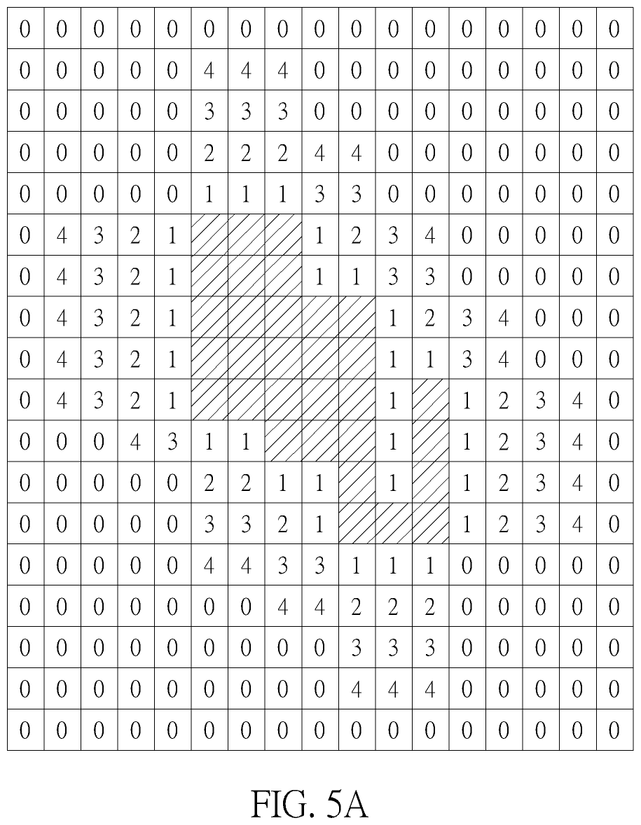

FIG. 4 shows the sequentially disposed sub-blocks of a flexible block according to an embodiment of the present invention. In FIG. 4, there are 7 sub-blocks with symbols A, B, C, D, E, F, and G in a flexible block and 3 sub-blocks with symbol “Blockage”. In this exemplified placement policy, the sub-blocks with symbol “Blockage” indicate the area which are occupied by the fixed blocks. In terms of sub-blocks with symbols from A to G, these sub-blocks are placed sequentially. For example, when sub-block C is not placed, then sub-block E cannot be placed at the position in FIG. 4 because the sub-block E is not attached to the edge of disposed sub-blocks A and B. The sub-blocks of each flexible block should be disposed next to the edge of disposed sub-blocks as shown in FIG. 4

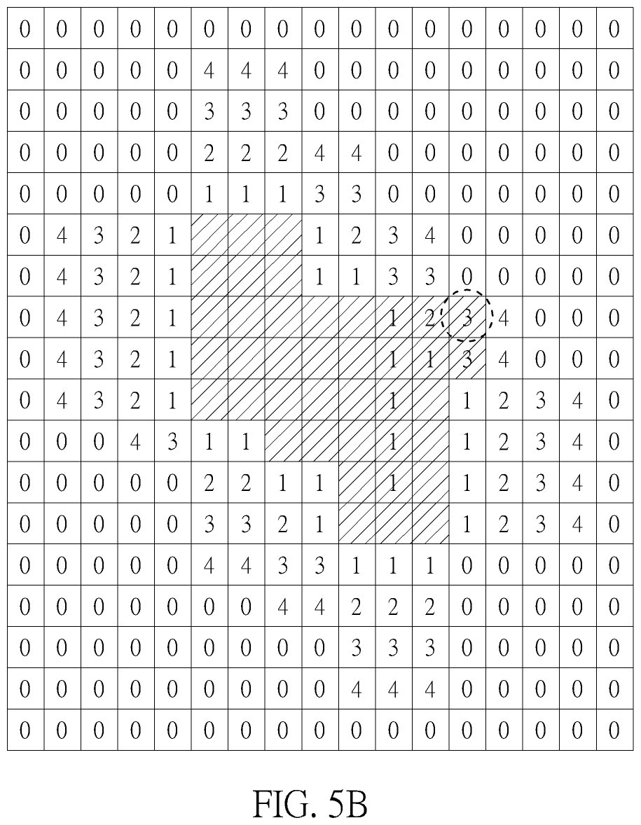

FIG. 5A shows the edge-depth map 212 according to an embodiment of the present invention. The edge-depth map is drawn according to two steps. The first step is generating a distance (such as 1, 2, 3 and 4 in FIG. 5A) from a grid to grids (shown as grids without numbers) occupied by the disposed sub-blocks of the flexible blocks. In this embodiment, the distance generated in the first step is a minimum distance. The second step is checking if the distance is between a maximum depth and 1. If so, assign the grid with the distance, else, assign the grid with 0. The drawing procedure can be made by a breadth-first search (BFS) or depth-first search (DFS) algorithm in an embodiment. The complete edge-depth map 212 is shown as FIG. 5A, and a placement decision can be made as FIG. 5B. FIG. 5B shows a placement decision in an edge-depth map 212 according to an embodiment of the present invention. The placement includes 6 grids with distance 1, 1 grid with distance 2, and 2 grids with distance 3.

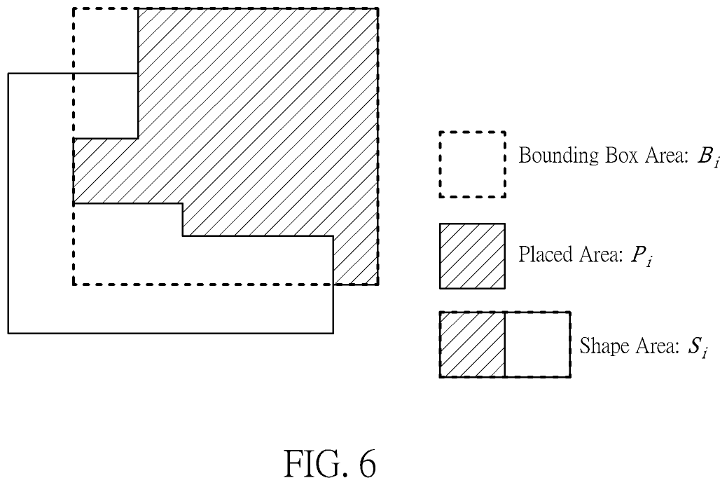

FIG. 6 shows the definitions of various areas that are utilized to calculate the rewards of the reinforcement learning according to an embodiment of the present invention. In FIG. 2, the embedding vector 206 is also inputted to a value network 208 to generate a value function for estimating a reward in a reinforcement learning. In an embodiment, the reward of the placement in the reinforcement learning is a negative sum of a shape reward and wirelength reward. The shape reward is generated by the following equation:

$$shape reward = {λ}_{s} {Σ}_{i = 0}^{N - 1} \frac{{B}_{i} - {S}_{i}}{{A}_{i}}$$

where
N is the number of flexible blocks;
λₛ is a hyperparameter of the shape reward;
Aᵢ is an area of an ith flexible block;
Bᵢ is a bounding box area of the disposed sub-blocks of the ith flexible block; and
Sᵢ is a shaped area in the bounding box area of the disposed sub-blocks of the ith flexible block.

The bounding box is a minimal rectangle which can frame all disposed sub-blocks of the ith flexible block as the dashed line shown in FIG. 6, and Bᵢ represent the bounding box area. The placed area Pᵢ is the area of all disposed sub-blocks of the ith flexible block as shown in FIG. 6. The total area of the ith flexible block is Aᵢ for shape reward calculation. Sᵢ is the shaped area which is bounded by the bounding box and is placed by fixed blocks and flexible blocks as shown in FIG. 6. The wirelength reward can be generated by the following equation:

wirelength reward=λ_{w}W_{L},
where
λ_{w} is a hyperparameter of the wirelength reward; and
W_{L} is a wirelength score generated by a routing tool according to a shape, a position and connections of the disposed sub-blocks of the flexible block.

By generating the wirelength reward and the shape reward, the reward can be generated as a negative sum of the wirelength reward and the shape reward, and the machine learning model can be trained according to the reward. The higher the reward, the better the solution.

The following table is a wirelength comparison of Early Floorplan Synthesis (EFS) and the rectilinear-block placement method 100.

| Design | Floorplan Method | Wirelength | |
|---|---|---|---|
| Chip Design I | EFS | 96.3M | |
| (14 flexible blocks) | rectilinear-block | 81.1M | (−15.8%) |
| | placement method | | |
| Chip Design II | EFS | 82.3M | |
| (15 flexible blocks) | rectilinear-block | 73.9M | (−10.2%) |
| | placement method | | |
| Chip Design III | EFS | 706.6M | |
| (21 flexible blocks) | rectilinear-block | 257.2M | (−63.6%) |
| | placement method | | |
| Chip Design IV | EFS | 2230.0M | |
| (15 flexible blocks) | rectilinear-block | 534.7M | (−76.0%) |
| | placement method | | |
| Chip Design V | EFS | 388.4M | |
| (15 flexible blocks) | rectilinear-block | 340.2M | (−12.4%) |
| | placement method | | |
| Chip Design VI | EFS | 514.0M | |
| (17 flexible blocks) | rectilinear-block | 502.0M | (−2.3%) |
| | placement method | | |
| Chip Design VII | EFS | 80.8M | |
| (16 flexible blocks) | rectilinear-block | 79.4M | (−1.7%) |
| | placement method | | |
| Chip Design VIII | EFS | 130.8M | |
| (13 flexible blocks) | rectilinear-block | 120.5M | (−7.8%) |
| | placement method | | |

In the table, the wirelengths generated by EFS are larger than the respective wirelengths generated by the rectilinear-block placement method of the present invention. That is, the wirelengths generated by EFS are larger than the respective wirelengths generated by the rectilinear-block placement method of the present invention. The lower the wirelength, the better the solution. Since the wirelength generated by the rectilinear-block placement method is lower than the wirelength generated by a prior art commercial tool, the quality and efficiency of circuit block placement is improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A rectilinear-block placement method, comprising:
disposing a first sub-block of each flexible block on a layout area of a chip canvas according to a reference position;
generating an edge-depth map relative to first sub-blocks of flexible blocks on the layout area;
predicting positions of second sub-blocks of the flexible blocks with depth values on the edge-depth map by a machine learning model; and
positioning the second sub-blocks on the layout area according to the predicted positions of the second sub-blocks of the flexible blocks.

2. The method of claim 1, further comprising if an area of disposed sub-blocks of a flexible block is less than an area of the flexible block, performing following steps:
generating an edge-depth map relative to the disposed sub-blocks of the flexible blocks on the layout area;
predicting a position of another sub-block of the flexible block with depth values on the edge-depth map by the machine learning model; and
positioning the another sub-block on the layout area according to the predicted position of the another sub-block of the flexible block.

3. The method of claim 2, wherein predicting the position of the another sub-block of the flexible block with the depth values on the edge-depth map by the machine learning model comprises:
inputting design features and a placement state to a feature extractor to generate an embedding vector with n dimensions;
inputting the embedding vector to a policy network to generate a two-dimensional tensor representing an action probability of position on M×N grids; and
applying the two-dimensional tensor on the edge-depth map to explore a potential placement of the another sub-block at an edge of disposed sub-blocks of the flexible block.

4. The method of claim 3, further comprising:
inputting the embedding vector to a value network to generate a value function for estimating a reward of a placement of the another sub-block.

5. The method of claim 4, wherein the reward of the placement is a negative sum of a shape reward and wirelength reward.

6. The method of claim 5, wherein the shape reward is generated by a following equation:
$$shape reward = {λ}_{s} {Σ}_{i = 0}^{N - 1} \frac{{B}_{i} - {S}_{i}}{{A}_{i}}$$
wherein
N is the number of flexible blocks;
λₛ is a hyperparameter of the shape reward;
Aᵢ is an area of an ith flexible block;
Bᵢ is a bounding box area of the disposed sub-blocks of the ith flexible block; and
Sᵢ is a shaped area in the bounding box area of the disposed sub-blocks of the ith flexible block.

7. The method of claim 5, wherein the wirelength reward is generated by a following equation:
wirelength reward=λ_{w}W_{L},
wherein
λ_{w} is a hyperparameter of the wirelength reward; and
W_{L} is a wirelength score generated by a routing tool according to a shape, a position and connections of the disposed sub-blocks of the flexible block.

8. The method of claim 3, wherein the feature extractor is a three layer convolution and a fully connected network.

9. The method of claim 3, wherein n is 48.

10. The method of claim 3, wherein inputting the embedding vector to the policy network to generate the two-dimensional tensor representing the action probability of position on the M×N grids is inputting the embedding vector to a fully connected network and a deconvolutional network to generate the two-dimensional tensor representing the action probability of position on the M×N grids.

11. The method of claim 3, wherein the design features comprise areas, reference positions, connection maps, and physical constraints of the flexible blocks, and areas of the disposed sub-blocks of the flexible blocks.

12. The method of claim 2, wherein generating the edge-depth map relative to the disposed sub-blocks of the flexible blocks on the layout area comprises:
generating a minimum distance from a grid to the disposed sub-blocks of the flexible blocks.

13. The method of claim 12, further comprising:
if the distance is between 1 and a maximum depth, assigning the grid with the distance.

14. The method of claim 12, further comprising:
if the distance is beyond a maximum depth, assigning the grid with 0.
